(19) United States
(12) Patent Application Publication
(10) Pub. No.: US 2005/0172997 A1
(43) Pub. Date: Aug. 11, 2005

(54) Back contact and back reflector for thin film silicon solar cells

(76) Inventors: Johannes Meier, Corcelles (CH); Ulrich Kroll, Corcelles (CH); Arthur Buchel, Rugell (LI)

Correspondence Address: PEARNE & GORDON LLP, 1801 EAST 9TH STREET, SUITE 1200, CLEVELAND, OH, 44114-3108, US

(21) Appl. No.: 11/044,118

(22) Filed: Jan. 27, 2005

Related U.S. Application Data
(60) Provisional application No. 60/542,382, filed on Feb. 6, 2004.

(51) Int. Cl. H01L 31/00

(52) U.S. Cl. 136/261; 438/57

(57) ABSTRACT

A thin film silicon solar cell for use in photovoltaic cells having a carrier substrate, a front transparent conductive oxide contact, a thin film silicon solar cell layer having at least one layer of hydrogenated microcrystalline silicon or nanocrystalline silicon, and a back contact having a transparent conductive oxide contact layer and a back reflective layer comprising a white pigmented dielectric reflective media.

This application claims the benefit of U.S. Provisional Patent Application Ser. No. 60/542,382 filed Feb. 6, 2004, the contents of which are incorporated herein by reference.

### FIELD OF THE INVENTION

The present invention relates to silicon solar cells and more specifically the present invention is directed to improving the light trapping capability of thin film silicon solar cells.

### BACKGROUND OF THE INVENTION

The light-trapping capability is related to the efficiency of thin film silicon solar cells. Improving the light-trapping capabilities of the silicon solar cell improves the cell efficiency and reduces the thickness of the cell, which improves the stability of thin film solar cells. Improving the light-trapping capability to produce a high quality light-trapping or light-confinement thin film silicon solar cell is attributed to the back contact. The back contact consists of two layers: 1) a highly textured transparent conductive oxide (TCO) front layer and 2) a highly reflective back layer.

FIG. 1 is an illustration of an amorphous silicon based thin film solar cell using conventional back contact technology. The cell 1 consists of a substrate 10, a transparent front contact layer 20, a thin film solar cell layer 30 based on pure amorphous silicon (a-Si:H) 34, and a back contact 60 comprising a TCO contact layer 40 and a highly reflective metallic film layer 50.

The back contact 60 must perform two functions during operation of the cell 1. First, the back contact 60 must act as a low resistance (or conversely, a highly conductive) electrical contact to the cell 1, which is the function of the TCO contact layer 40 and second, the back contact 60 must reflect weakly absorbed light that reaches the back reflective layer, which is the function of the reflective layer 50. In general, these conditions are realized in thin film silicon solar cells with a back contact 60 combination consisting of a thin TCO layer 40 approximately 0.1 μm thick for refractive index matching and a highly reflective metallic film layer 50 such as aluminum or silver approximately 0.1-0.5 μm thick as shown in FIG. 1.

The conventional technology described above has several disadvantages. First, the reflectivity and conductivity of metallic back contacts based on silver or aluminum are very sensitive to moisture and oxidation when used in photo voltaic (PV) modules over long-term outdoor applications. If the PV modules are not properly sealed or if the seal breaks down over a period of time and becomes weak the sensitivity of the back contacts will degrade thus leading to a substantial decrease in the reflectivity properties of the metallic film and ultimately leading to a decrease in performance of the PV modules. Second, the application of the metallic back reflector involves an additional production step thus requiring metal deposition equipment. Whereas, in the present invention the metal deposition equipment is not required. Third, for optimal performance of the metallic back reflective layer 50 the TCO contact layer 40 must be a precise thickness. This precision requirement requires strict, precise regulation of the TCO contact layer during the deposition process. The regulation process is typically expensive which leads to increased production costs. In order to reduce cost the regulation process may at times be omitted which leads to poor cell quality. Another disadvantage is that it is difficult to provide a good adherence of the metallic back reflective layer to the cell, which leads to problems in long term evaluation of solar cells.

The present invention overcomes the aforementioned disadvantages by providing a back contact consisting of a combination of a thicker TCO contact layer and a white diffusive non-metallic media as the reflective layer.

Regarding amorphous silicon single-junction p-i-n solar cells, the use of a ZnO-layer as an electrical contact and a white paint paste as the reflective layer has been disclosed in Solar Energy Materials and Solar Cells 31 p. 253-261 (1993) by R. van den Berg, H. Calwer, P. Marklstorfer, R. Meckes, F. W. Schulze, K.-D. Ufert, and H. Vogt. Because amorphous silicon absorbs light in the visible portion of the light spectrum, e.g. light having a wavelength shorter than 730 nm, the white paint applied has to back scatter light only in the visible light range. The lower wavelength limit down to which the back scattering is required depends on the absorption coefficient and the thickness of the absorbing solar cell. For a shorter wavelength the absorption coefficient increases. Thus, for a given thickness of an absorbing solar cell the short wavelength light does not reach the back reflective layer. Thus, when the wavelength of the light is in the visible range a back reflective layer is not required. However, for microcrystalline silicon cells having a low absorption coefficient the light having a wavelength near the infrared region, e.g. over 1100 nm, cannot be absorbed by the silicon layer and thus the light would be lost without a back reflective layer. Therefore, a back contact having efficient back scattering properties in the long wavelength (i.e. infrared) region is required but has not been considered.

Furthermore, the physical properties and the behavior of two-component white dielectric coatings pertaining to the composition of small particles of approximately wavelength size in a dielectric medium a with different index of refraction has been disclosed in Prog. Photovolt: Res. Appl. 7 p. 261-274 (1999) by J. E. Cotter, R. B. Hall, M. G. Mauk and A. M. Barnett. In the conclusion of the article the application of such dispersed particles for back reflective layers not only in thin film silicon cells but also in amorphous cells is suggested. Furthermore, the introduction of dispersed particles in Ethyl-vinyl-acetate foils is proposed. However, the combination of such pigmented dielectric reflectors with TCO films has neither been described nor considered. Thus, it is the combination of a TCO film layer and a white reflective layer that leads to the optimal contribution of the back contact to the light trapping capability of the thin film silicon solar cell.

### BRIEF SUMMARY OF THE INVENTION

In accordance with one aspect of the present invention a photovoltaic cell is provided comprising a carrier substrate layer, a front contact layer deposited on the substrate, a thin film silicon solar cell layer deposited on the substrate, and a back contact deposited on the thin film silicon solar cell layer where the back contact comprises a transparent conductive oxide contact layer and a pigmented dielectric back reflective white media layer.

In accordance with another aspect of the present invention a thin film silicon solar cell is provided comprising a back contact having a transparent conductive oxide contact layer and a pigmented dielectric back reflective white media layer adhered to the transparent conductive oxide contact layer where the transparent conductive oxide contact layer has a thickness in the range of 0.5 μm to 5 μm.

Additional benefits and advantages of the present invention will become apparent to those skilled in the art to which it pertains upon a reading and understanding of the following detailed specification.

### BRIEF DESCRIPTION OF THE DRAWINGS

The invention may take physical form in certain parts and arrangement of parts, a preferred embodiment of which will be described in detail in this specification and illustrated in the accompanying drawings that form a part of the specification.

FIG. 1 is an illustration of an amorphous silicon based thin film solar cell using conventional back contact technology.

FIG. 2 is an illustration of a thin film silicon solar cell using back contact technology according to the present invention.

FIGS. 3a-3c show three embodiments of the thin film silicon solar cell according to the present invention.

### DETAILED DESCRIPTION OF THE INVENTION

It should be noted that in the following description the term “reflective” or “reflector” is used in describing the white reflective media layer even though the white media according to the present invention does not necessarily act as a perfect specular reflector as does the metal reflective layer. However, the white reflective media re-scatters the light in many spatial directions from one incident beam. Thus it is better described as diffusive reflector.

Referring now to the drawings, FIG. 2 shows a thin film silicon solar cell 1 according to the present invention that may be used in a wafer based silicon PV module. The cell 1 includes a carrier substrate layer 10, a front contact layer 20, a silicon solar cell layer 30, and a back contact 62 comprising a TCO contact layer 42 and a back reflective layer 52.

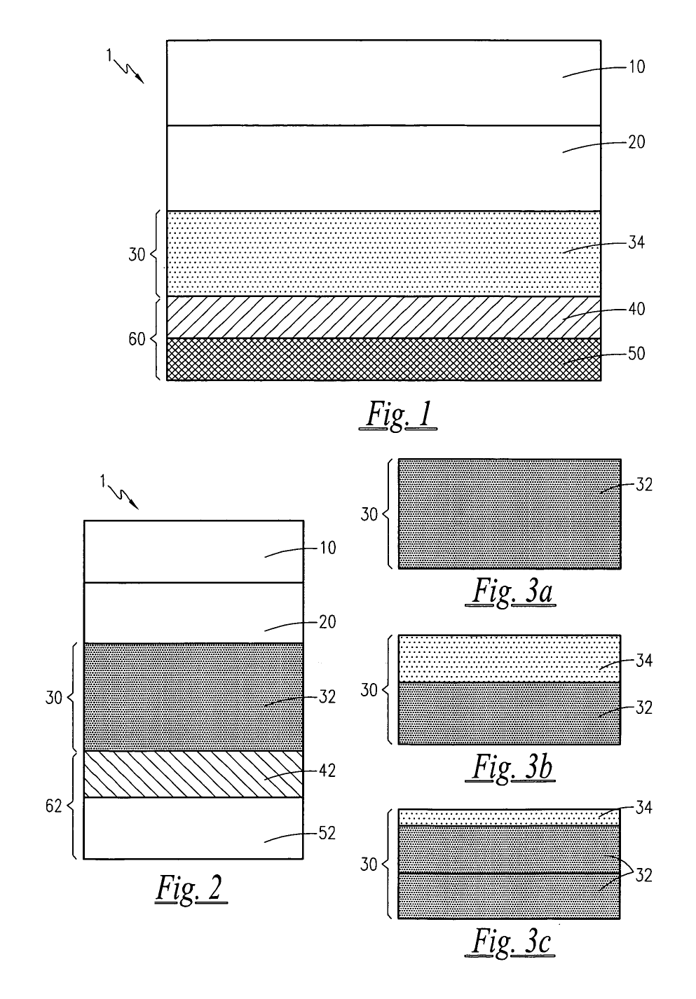

The substrate layer 10 and the front contact layer 20 are similar to the layers 10 and 20 shown in FIG. 1. More specifically, the substrate layer 10 is a transparent layer and may consist of any material known in the art such as glass. The front contact layer 20 consists of a TCO layer and may be any type of transmissive and conductive material known in the art such as zinc-oxide (ZnO), indium-tin-oxide (ITO), or tin-dioxide (SnO2).

Referring to FIGS. 2 and 3a-3c, the thin film silicon solar cell layer 30 comprises hydrogenated microcrystalline silicon (μc-Si:H) 32 or nanocrystalline silicon. Microcrystalline silicon 32 has a smaller band gap as compared to amorphous silicon 34. Thus, microcrystalline silicon 32 has an extended spectral absorption into the infrared region, over 1100 nm, as opposed to pure amorphous silicon 34 as shown in FIG. 1. Further, in combination layers, such as those shown in FIGS. 3b-3c, microcrystalline silicon 32 has additional qualities that allow it to function as a bottom or middle sub-layer. For example, FIG. 3b, referred to as a stacked tandem cell, has a first sub-layer consisting or amorphous silicon 34 and a second sub-layer consisting of microcrystalline silicon 32. FIG. 3c, referred to a triple junction cell, has a first sub-layer consisting of amorphous silicon 34 and second third sub-layers consisting of microcrystalline silicon 32. These types of cells shown in FIGS. 3a-3c all have an extended infrared spectral performance compared to pure amorphous silicon 34 as shown in FIG. 1.

Referring again to FIG. 2, the TCO contact layer 42 is similar to the TCO contact layer 40 of FIG. 1 and may be any type of transmissive and conductive material known in the art such as zinc-oxide (ZnO), indium-tin-oxide (ITO), or tin-dioxide (SnO2). However, the TCO layer 42 of FIG. 2 has a thickness larger than the thickness of the TCO layer 40 used in the conventional technology as described above. The thickness of the TCO layer 42 is typically in the range of 0.5 μm to 5 μm. The increased thickness of the TCO layer 42 compared to the conventional design provides the high electrical conductivity required for a back contact 62 in order to collect the photo current (e.g. in monolithic series interconnection of segments in a thin-film solar cell large-area module). The interface between the TCO contact layer 42 and the thin film silicon solar cell layer 30 may be flat or rough but is preferably textured.

The back reflective layer 52 consists of an highly reflective (e.g. white) dielectric media. The white media consists of pigments dispersed in a medium. Thus, the back reflective layer 52 is commonly known in the art as a pigmented dielectric reflector. The pigments may be any type of pigment known in the art such as oxides (e.g. titanium-dioxide (TiO2) or barium sulfate (BaSO4) particles), nitrides, carbides, etc. The medium may be, but is not limited to, any medium that has adequate stability and is capable of ensuring the dispersion of the pigments such as paint or polymers for plastic. The diameter of the pigments range from 0.2 μm to 2 μm and are mixed in a range of 10-100%, by volume, in the medium. Further, the ratio of refractive indices of the pigment to the medium is 1.4 to 2. The interface between the TCO contact layer 42 and the back reflective layer 52 may be flat or rough but is preferably textured.

In one embodiment of the present invention a white paint paste may be used as the back reflective layer 52. Any painting product known in the art such as those used in the automotive industry, building coatings, etc. may be used. For example, Farbenfabrik Pröll GmbH & Co, PUR-ZK 945, Noritemp GN 945, ZK-Farbe 944, ZK-Farbe 945. Further, unlike the metallic film the white paint provides a better adherence to the cell 1.

In another embodiment a “foil”-type back reflector may be used as the back reflective layer 52. In this embodiment the back reflective layer 52 is a white foil based on Tedlar (PVF Polyvinyl fluoride from Du Pont). The white foil is adhered to the TCO layer 42 by any means known in the art such as glueing, for example, with an EVA foil. Examples of such a white foil material based on Tedlar (PVF) are commercial products like Akasol PTL 3-38/75 TWH or Akasol PTL 2-38/75 TWH produced by the German company KREMPEL or products like ICOSOLARR W/W 2116, ICOSOLARR W/W 0898, ICOSOLARR W/W 2442, ICOSOLAR R W/W 2482, and ICOSOLARR W/W 0711 produced by the Austrian company ISOVOLTA. Further, the foil-type reflector functions as a back encapsulation of the thin film silicon solar cell 1. As a result the weight of the PV modules is reduced because the double glass laminate is not required thereby reducing manufacturing costs.

In yet another embodiment, an Ethyl-Vinyl-Acetate (EVA) foil or layer which itself represents the pigmented dielectric reflector can be used as the back reflective layer 52. The EVA foil may be used with or without an additional protective foil.

According to the present invention, as described above, the light trapping capability is increased as compared to metallic reflectors because the white reflective media acts as a diffusive back reflector. Thus, any light that reaches the back reflective layer 52 is repeatedly scattered throughout the medium. The light is eventually reflected back to the thin film silicon solar cell layer 30 where it is absorbed. Therefore, any light that is initially lost due the absorption inefficiency of the thin film silicon solar cell layer 30 is reflected back to the silicon layer 30. Further, as mentioned above, the reflective properties of the metallic reflective layer 50 such as silver or aluminum are very sensitive to humidity and sulfur contamination for silver. This leads to an oxidation of the metal thus reducing the reflective efficiency of the metallic reflective layer 50. Whereas, the white reflective media have properties that make it more resistive to moisture. The durability of the cells can be further improved by applying a laquer coating to the cell under atmospheric conditions.

While specific embodiments of the invention have been described and illustrated, it is to be understood that these embodiments are provided by way of example only and that the invention is not to be construed as being limited thereto but only by proper scope of the following claims.

1. A photovoltaic cell comprising:
a carrier substrate layer;
a front contact layer deposited on the substrate;
a thin film silicon solar cell layer deposited on the front contact layer; and, a back contact deposited on the thin film silicon solar cell layer wherein the back contact comprises a transparent conductive oxide contact layer and a pigmented dielectric back reflective white media layer.

2. The photovoltaic cell of claim 1, wherein the pigmented dielectric back reflective white media further comprises:
a medium;
pigments dispersed in the medium in the range of 10-100% by volume and wherein the diameter of the pigments range from 0.2 μm to 2 μm.

3. The photovoltaic cell of claim 2, wherein the ratio of refractive indices of the pigment to the medium is 1.4 to 2.

4. The photovoltaic cell of claim 3, wherein the pigmented dielectric back reflective white media consists of a white paint.

5. The photovoltaic cell of claim 3, wherein the pigmented dielectric back reflective white media consists of a white foil.

6. The photovoltaic cell of claim 3, wherein the pigmented dielectric back reflective white media consists of an ethyl-vinyl-acetate foil.

7. The photovoltaic cell of claim 1, wherein the transparent conductive oxide layer has a thickness in the range of 0.5 μm to 5 μm.

8. The photovoltaic cell of claim 1, wherein the thin film silicon solar layer comprises hydrogenated microcrystalline silicon or nanocrystalline silicon.

9. The photovoltaic cell of claim 1, wherein the thin film silicon solar layer further comprises a first sub-layer comprising amorphous silicon and a second sub-layer comprising hydrogenated microcrystalline silicon or nanocrystalline silicon.

10. The photovoltaic cell of claim 6, wherein the thin film silicon solar layer further comprises a third sub-layer comprising hydrogenated microcrystalline silicon or nanocrystalline silicon.

11. The photovoltaic cell of claim 1, wherein the front contact consists of a transparent conductive oxide layer.

12. The photovoltaic cell of claim 11, wherein the interface between the transparent conductive oxide layers and an adjacent layer may be flat or textured.

13. A thin film silicon solar cell comprising:
a back contact having a transparent conductive oxide contact layer; and,
a pigmented dielectric back reflective white media layer adhered to the transparent conductive oxide contact layer,
wherein the transparent conductive oxide contact layer has a thickness in the range of 0.5 μm to 5 μm.

14. The thin film silicon solar cell of claim 13, wherein the pigmented dielectric back reflective white media further comprises:
a medium;
pigments dispersed in the medium in the range of 10-100% by volume and wherein the diameter of the pigments range from 0.2 μm to 2 μm.

15. The thin film silicon solar cell of claim 14, wherein the ratio of refractive indices of the pigment to the medium is 1.4 to 2.

16. The thin film silicon solar cell of claim 15, wherein the interface between the transparent conductive oxide layers and an adjacent layer may be flat or textured.

17. The thin film silicon solar cell of claim 16, wherein the pigmented dielectric back reflective white media consists of a white paint.

18. The thin film silicon solar cell of claim 16, wherein the pigmented dielectric back reflective white media consists of a white foil.

19. The thin film silicon solar cell of claim 16, wherein the pigmented dielectric back reflective white media consists of an ethyl-vinyl-acetate foil.

20. A method of manufacturing a thin film silicon solar cell comprising the steps of:
providing a carrier substrate;
depositing a first transparent conductive oxide layer on the substrate;
depositing at least one sub-layer of hydrogenated microcrystalline silicon or nanocrystalline silicon on the transparent conductive oxide layer;
depositing a second thicker transparent conductive oxide layer on the thin film silicon solar cell;
depositing a reflective white media on the second transparent conductive oxide layer

21. The method of claim 19 further comprising the steps of:
depositing a sub-layer of amorphous of silicon on the first transparent conductive oxide layer; and,
depositing a second sub-layer of hydrogenated microcrystalline silicon or nanocrystalline silicon on the transparent conductive oxide layer.
